(19) United States
(12) Patent Application Publication
(10) Pub. No.: US 2023/0137230 A1
(43) Pub. Date: May 4, 2023

(54) RESIN COMPOSITION, METHOD FOR PRODUCING DISPLAY DEVICE OR LIGHT RECEPTION DEVICE USING SAME, SUBSTRATE AND DEVICE

(71) Applicant: Toray Industries, Inc., Tokyo (JP)

(72) Inventors: Daichi Miyazaki, Otsu-shi, Shiga (JP); Tomoki Ashibe, Otsu-shi, Shiga (JP)

(73) Assignee: Toray Industries, Inc., Tokyo (JP)

(21) Appl. No.: 17/913,472

(22) PCT Filed: Mar. 22, 2021
(86) PCT No.: PCT/JP2021/011711

§ 371 Date: Sep. 22, 2022

(30) Foreign Application Priority Data
Mar. 24, 2020 (JP) 2020-052296
Aug. 3, 2020 (JP) 2020-131460

(51) Int. Cl. C08L 25/02; C08L 41/00

(52) U.S. Cl. CPC C08L 25/02; C08L 41/00; C08L 2201/10; C08L 2201/08; C08L 2203/204

(57) ABSTRACT

A device substrate is provided with an increased light transmittance that is a resin film resistant to thermal decomposition in high temperature processes, along with a production method for a device substrate, a device, and a production method for a device, where a resin composition designed to produce a resin film to be used as a substrate for a display device or light receiving device, comprises (a) a resin that has a repeating unit as represented by the chemical formula (1) or (2) as a primary component and (b) a chemical compound as represented by the chemical formula (3) and/or a condensation product thereof,

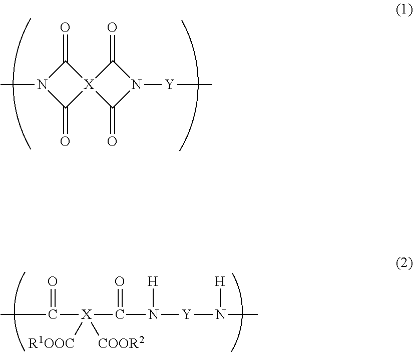

wherein in the chemical formulae (1) and (2), X, Y, R¹ and R² are defined, and

Si(OR¹¹)ₙ(R¹²)₄₋ₙ (3)

wherein in the chemical formula (3), R¹¹ and R¹² are as defined.

### CROSS REFERENCE TO RELATED APPLICATIONS

This application is the U.S. National Phase application of PCT/JP2021/011711, filed Mar. 22, 2021, which claims priority to Japanese Patent Application No. 2020-052296, filed Mar. 24, 2020 and Japanese Patent Application No. 2020-131460, filed Aug. 3, 2020, the disclosures of these applications being incorporated herein by reference in their entireties for all purposes.

### FIELD OF THE INVENTION

The present invention relates to a resin composition, a method for producing a displaying device or light receiving device therefrom, a substrate, and a device.

### BACKGROUND OF THE INVENTION

Having good electrical insulation properties, heat resistance, and mechanical properties, polyimide has been used as material for various electronic devices such as semiconductors and display devices. Recently, production of shock resistant, flexible displays has become possible by applying polyimide film to the substrates of image display devices such as organic EL displays, electronic papers, and color filters.

Materials to be incorporated in electronic devices are required to be so high in heat resistance as to resist high temperature processes used for device production. To produce a product that requires transparency, in particular, it is necessary to adopt a substrate material that is high in both heat resistance and transparency.

For example, Patent document 1 proposes a process for producing an organic EL display by using a polyimide substrate with high heat resistance. Patent document 2 further proposes a process for producing electronic devices such as color filter, organic EL display, and touch panel by using a polyimide substrate with high transparency. In addition, Patent document 3 reports a process for using an alkoxysilane modified polyimide precursor to produce a polyimide film that serves as a transparent substrate.

### PATENT DOCUMENTS

Patent document 1: International Publication WO 2017/099183
Patent document 2: International Publication WO 2017/221776
Patent document 3: Japanese Unexamined Patent Publication (Kokai) No. 2016-188367

### SUMMARY OF THE INVENTION

In the case of the polyimide resin film described in Patent document 1, the resin film fails to have a sufficiently high light transmittance and therefore it has the disadvantage of being unsuitable for producing products that require transparency. The polyimide resin films described in Patent document 2 and Patent document 3 are disadvantageous in that layers formed on the polyimide resin films are likely to be peeled easily. Thus, the main object of the present invention is to provide a resin composition suited to form a resin film having transparency and serving to produce an electronic device and characterized in that layers formed on the resin composition will not be peeled in high temperature processes.

The present invention relates to a resin composition designed to produce a resin film to be used as a substrate for a display device or light receiving device, including (a) a resin that has a repeating unit as represented by the chemical formula (1) or (2) as primary component and (b) a chemical compound as represented by the chemical formula (3) and/or a condensation product thereof and forming, when heated at 430° C. for 30 minutes, a resin film having a weight loss starting temperature of 400° C. or more and showing a yellowness index of 3.5 or less when being 10 μm thick.

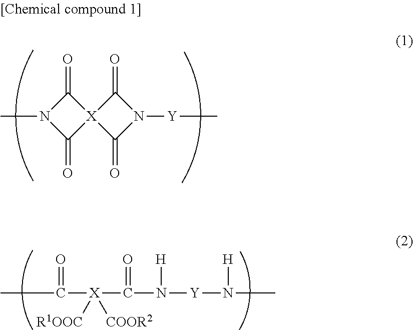

In the chemical formulae (1) and (2), X denotes a tetravalent tetracarboxylic acid residue containing 2 or more carbon atoms and Y denotes a divalent diamine residue containing 2 or more carbon atoms. R¹ and R² each independently denote a hydrogen atom, a hydrocarbon group containing 1 to 10 carbon atoms, an alkyl silyl group containing 1 to 10 carbon atoms, an alkali metal ion, an ammonium ion, an imidazolium ion, or a pyridinium ion.

[Chemical compound 2]

Si(OR¹¹)ₙ(R¹²)₄₋ₙ (3)

In the chemical formula (3), R¹¹ denotes a hydrogen atom or a hydrocarbon group containing 1 to 10 carbon atoms. R¹² denotes a hydrocarbon group containing 1 to 10 carbon atoms. Furthermore, n represents an integer of 2 to 4.

The present invention also relates to a substrate for a display device or light receiving device that contains a resin having a repeating unit as represented by the chemical formula (1) as primary component and polysiloxane and shows a weight loss starting temperature of 400° C. or more and a yellowness index of 3.5 or less.

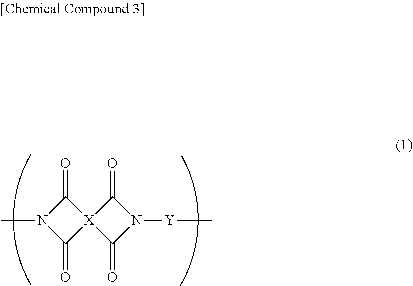

In the chemical formula (1), X denotes a tetravalent tetracarboxylic acid residue containing 2 or more carbon atoms and Y denotes a divalent diamine residue containing 2 or more carbon atoms.

The resin composition according to the present invention has transparency and forms a resin film that serves as a substrate for an electronic device. The resin film is little likely to suffer peeling of a layer formed on the resin film in a high temperature process for producing an electronic device and can be used suitably to produce a product that requires transparency.

### DETAILED DESCRIPTION OF EMBODIMENTS OF THE INVENTION

Embodiments of the present invention are described in detail below. It should be noted, however, that the present invention is not limited to the embodiments described below and may be modified appropriately to suit particular objectives and purposes.

<Resin Composition>

The resin composition according to the present invention is a resin composition designed to serve for producing a resin film to be used as a substrate for a display device or light receiving device and includes (a) a resin having a repeating unit as represented by the chemical formula (1) or (2) as primary component, hereinafter occasionally referred to as the resin (a), and (b) a chemical compound as represented by the chemical formula (3) and/or a condensation product thereof, hereinafter occasionally referred to as the compound etc. (b).

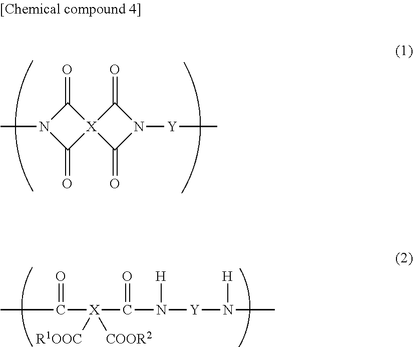

In the chemical formulae (1) and (2), X denotes a tetravalent tetracarboxylic acid residue containing 2 or more carbon atoms and Y denotes a divalent diamine residue containing 2 or more carbon atoms. R¹ and R² each independently denote a hydrogen atom, a hydrocarbon group containing 1 to 10 carbon atoms, an alkyl silyl group containing 1 to 10 carbon atoms, an alkali metal ion, an ammonium ion, an imidazolium ion, or a pyridinium ion.

[Chemical compound 5]

Si(OR¹¹)ₙ(R¹²)₄₋ₙ (3)

In the chemical formula (3), R¹¹ denotes a hydrogen atom or a hydrocarbon group containing 1 to 10 carbon atoms. R¹² denotes a hydrocarbon group containing 1 to 10 carbon atoms. Furthermore, n represents an integer of 2 to 4.

A resin film formed by heating the resin composition according to the present invention at 430° C. for 30 minutes has a weight loss starting temperature of 400° C. or more. The weight loss starting temperature is preferably 430° C. or more, and more preferably 450° C. or more. On the other hand, the weight loss starting temperature is preferably 600° C. or less. If the weight loss starting temperature of the resin film is 400° C. or more, a layer formed on the resin film will be less likely to suffer peeling, which is also called film lifting, that can be caused by gas generation from the resin film in a high temperature process for producing an electronic device. The weight loss temperature of the resin film is preferably as high as possible because it allows the process for producing an electronic device to be implemented at a higher temperature. The purpose of defining a weight loss starting temperature of a resin film produced by baking at 430° C. for 30 minutes will be described later.

In addition, when having a thickness of 10 μm, the resin film shows a yellowness index of 3.5 or less. The yellowness index is preferably 3.0 or less, more preferably 2.5 or less, and still more preferably 2 or less. On the other hand, it is preferably −3 or more, more preferably −2.5 or more, and still more preferably −2 or more. If showing a yellowness index of 3.5 or less, the resin film can serve suitably to produce a product that is required to be colorless and transparent.

For the present invention, the weight loss starting temperature of a resin film is measured by using a thermogravimetric analyzer. Heating is performed under the following conditions: a test piece is heated to 150° C. at a heating rate of 10° C./min and maintained at 150° C. for 30 minutes (first stage); then the test piece is cooled to room temperature at a cooling rate of 10° C./min (second stage); and it is heated again at a heating rate of 10° C./min (third stage). The temperature at which the weight loss starts is determined as the weight loss starting temperature.

For the present invention, the yellowness index of a resin film is measured according to JIS K 7373:2006. Useful methods for measuring the thickness of a resin film include noncontact type measuring methods such as the use of an optical interference type film thickness measuring device and ellipsometer, contact type measuring methods such as the use of a stylus profiler, micrometer, and dial gage, and electromagnetic measure methods such as the use of a length measuring machine equipped with encoder.

(Resin (a))

The chemical formula (1) represents a repeating unit structure of a polyimide, and the chemical formula (2) represents a repeating unit structure of polyamic acid etc. Polyamic acid is produced through reaction between a tetracarboxylic acid and a diamine compound, as described later. Then, polyamic acid can be converted into polyimide, which is a heat resistant resin, by heating, chemical treatment, etc.

In a resin having a repeating unit as represented by the chemical formula (1) or (2) as primary component, the number of repetitions of that repeating unit accounts for 50% or more of the number of repetitions of all repeating units. In the resin (a), the number of repetitions of that repeating unit preferably accounts for 80% or more, more preferably 90% or more, of the number of repetitions of all repeating units. If it is in the above range, it ensures that the resin has a heat resistance required to serve as a substrate for a display device or light receiving device.

In the chemical formulae (1) and (2), X denotes a tetravalent tetracarboxylic acid residue containing 2 or more carbon atoms wherein the tetravalent tetracarboxylic acid residue contains hydrogen and carbon as essential components and is preferably a tetravalent organic group containing 2 to 80 carbon atoms that may contain one or more elements selected from the group consisting of boron, oxygen, sulfur, nitrogen, phosphorus, silicon, and halogens, more preferably a tetravalent hydrocarbon group containing 2 to 80 carbon atoms. For each of boron, oxygen, sulfur, nitrogen, phosphorus, silicon, and halogens, the number of atoms included is preferably in the range of 20 or less, and more preferably in the range of 10 or less.

There are no specific limitations on the tetracarboxylic acid that gives X, and generally known ones can be used. They include, for example, pyromellitic acid, 3,3′,4,4′-biphenyltetracarboxylic acid, 2,3,3′,4′-biphenyltetracarboxylic acid, 2,2′,3,3′-biphenyltetracarboxylic acid, 3,3′,4,4′-benzophenonetetracarboxylic acid, 2,2-bis(3,4-dicarboxyphenyl)hexafluoropropane, bis(3,4-dicarboxyphenyl)sulfone, bis(3,4-dicarboxyphenyl)ether, 9,9-bis(3,4-dicarboxyphenyl)fluorene, cyclobutanetetracarboxylic acid, 1,2,3,4-cyclopentanetetracarboxylic acid, and 1,2,4,5-cyclohexanetetracarboxylic acid, and tetracarboxylic acids as specified in International Publication WO 2017/099183. Of these, 3,3′,4,4′-biphenyltetracarboxylic acid, 2,3,3′,4′-biphenyltetracarboxylic acid, 2,2′,3,3′-biphenyltetracarboxylic acid, and bis(3,4-dicarboxyphenyl)ether are preferable from the viewpoint of producing a resin film having both thermal decomposition resistance and high transparency. In particular, 3,3′,4,4′-biphenyltetracarboxylic acid is the most preferable.

These tetracarboxylic acids may be used in their original form or in the form of acid anhydride, active ester, or active amide. Of these, anhydrides are preferred because they do not generate by-products during polymerization. Furthermore, two or more thereof may be used in combination.

Of the repeating units represented by the chemical formula (1) or (2) existing in the resin, those repeating units in which X is a structure as represented by the chemical formula (12) preferably account for 50 mol % or more.

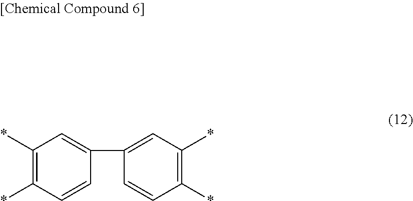

The tetracarboxylic acid that gives a structure as represented by the chemical formula (12) as X is 3,3′,4,4′-biphenyltetracarboxylic acid. If 3,3′,4,4′-biphenyltetracarboxylic acid is used as the tetracarboxylic acid, the weight loss temperature of the resin film according to the present invention can be further improved and the increase in the yellowness index can be further suppressed.

In the chemical formulae (1) and (2), Y contains hydrogen and carbon as essential components and is preferably a divalent organic group containing 2 to 80 carbon atoms that may contain one or more elements selected from the group consisting of boron, oxygen, sulfur, nitrogen, phosphorus, silicon, and halogens, more preferably a divalent hydrocarbon group containing 2 to 80 carbon atoms. For each of boron, oxygen, sulfur, nitrogen, phosphorus, silicon, and halogens, the number of atoms included is preferably in the range of 20 or less, and more preferably in the range of 10 or less.

There are no specific limitations on the diamine that gives Y, and generally known ones can be used. They include, for example, m-phenylenediamine, p-phenylenediamine, 4,4′-diaminobenzanilide, 3,4′-diaminodiphenylether, 4,4′-diaminodiphenylether, 3,3′-diaminodiphenylsulfone, 4,4′-diaminodiphenylsulfone, 3,4′-diaminodiphenylsulfone, 2,2′-dimethyl-4,4′-diaminobiphenyl, 2,2′-di(trifluoromethyl)-4,4′-diaminobiphenyl, 1,4-bis(4-aminophenoxy)benzene, 1,3-bis(3-aminophenoxy)benzene, 1,3-bis(4-aminophenoxy)benzene, bis(3-amino-4-hydroxyphenyl)hexafluoropropane, bis(4-(4-aminophenoxy)phenyl)sulfone, 9,9-bis(4-aminophenyl)fluorene, 4-aminobenzoic acid 4-aminophenyl ester, ethylenediamine, propylenediamine, butanediamine, cyclohexanediamine, 4,4′-methylenebis(cyclohexylamine), 1,3-bis(3-aminopropyl)tetramethyldisiloxane, and those diamines specified in International Publication WO 2017/099183. Of these, 3,3′-diaminodiphenylsulfone, 4,4′-diaminodiphenylsulfone, 3,4′-diaminodiphenylsulfone, and bis(4-(4-aminophenoxy)phenyl)sulfone are preferable from the viewpoint of producing a resin film having both thermal decomposition resistance and high transparency. In particular, 4,4′-diaminodiphenylsulfone is the most preferable.

These diamines may be used in their original form or in the form of corresponding trimethylsilylated diamines. Furthermore, two or more thereof may be used in combination.

Of the repeating units represented by the chemical formula (1) or (2) existing in the resin, those repeating units in which Y is a structure as represented by the chemical formula (11) preferably account for 50 mol % or more.

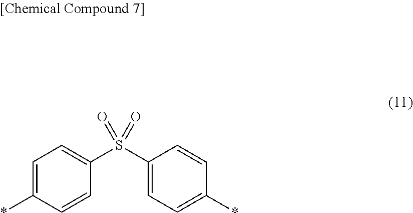

The diamine that gives a structure as represented by the chemical formula (11) as Y is 4,4′-diaminodiphenylsulfone. If 4,4′-diaminodiphenylsulfone is used as the diamine, the yellowness index of the resin film according to the present invention can be further decreased and the decrease in the weight loss temperature can be further suppressed.

In the resin (a), the chains may be terminated with an end capping agent. Reacting it with an end capping agent can serve to control the molecular weight of the polyimide precursor in a preferable range.

If it has a diamine compound as the terminal monomer, the amino group can be capped by using a dicarboxylic anhydride, monocarboxylic acid, monocarboxylic chloride compound, monocarboxylic acid active ester compound, dialkyl dicarbonate, or the like as end capping agent.

If the terminal monomer is a dianhydride, the anhydride group can be capped by using a monoamine, monoalcohol, or the like as end capping agent.

When measured by gel permeation chromatography, the resin (a) preferably has a polystyrene-based weight average molecular weight of 200,000 or less, more preferably 150,000 or less, and still more preferably 100,000 or less. If it is this range, the viscosity increase can be prevented even in the case of a resin composition with a high concentration. On the other hand, the weight average molecular weight is preferably 5,000 or more, more preferably 10,000 or more, and still more preferably 30,000 or more. If the weight average molecular weight is 30,000 or more, resin compositions formed therefrom will not suffer from a significant decrease in viscosity and can maintain higher coatability.

There are no specific limitations on the number of repetitions in the chemical formulae (1) and (2) as long as the weight average molecular weight is in the above range. It is preferably 5 or more, and more preferably 10 or more. In addition, it is preferably 1,000 or less, and more preferably 500 or less.

(Compound Etc. (b))

A compound (b) as represented by the chemical formula (3) forms a siloxane bond through a hydrolysis of the alkoxy group (OR¹¹) and subsequent dehydration condensation. As this reaction is repeated, polysiloxane is produced from a compound as represented by the chemical formula (3). As the polysiloxane is formed in the resin film, the light transmittance can be improved while preventing the resin film from deteriorating in resistance to thermal decomposition. Therefore, the yellowness index can be lowered while increasing the weight loss starting temperature of the resin film.

It is preferable for the compounds represented by the chemical formula (3) to contain a compound as represented by the chemical formula (31).

[Chemical compound 8]

Si(OR¹¹)₃(R¹²) (31)

In the chemical formula (31), R¹¹ denotes a hydrogen atom or a hydrocarbon group containing 1 to 10 carbon atoms. R¹² denotes a hydrocarbon group containing 1 to 10 carbon atoms. Here, in R¹¹ and R¹², each hydrocarbon group containing carbon atoms 1 to 10 has no reactive functional groups. A compound as represented by the chemical formula (31) has a smaller number of alkoxy groups (OR¹¹) than Si(OR¹¹)₄, and accordingly, all alkoxy groups are likely to be hydrolyzed completely. Therefore, the resin film will not suffer such an increase in yellowness index as seen when unreacted alkoxy groups are degraded at an elevated temperature. In addition, unlike the case of a polysiloxane formed only from Si(OR¹¹)₄, the inclusion of a compound as represented by the chemical formula (31) leads to a polysiloxane containing a hydrocarbon group R¹², realizing a higher compatibility with organic polymers. Furthermore, unlike the case of a polysiloxane formed only from Si(OR¹¹)₂(OR¹²)₂, a branched structure is produced to form a network-like polysiloxane, leading to an increased heat resistance.

Examples of a compound as represented by the chemical formula (3) include methyltrimethoxysilane, methyltriethoxysilane, ethyltrimethoxysilane, ethyltriethoxysilane, hexyltrimethoxysilane, hexyltriethoxysilane, phenyltrimethoxysilane, and phenyltriethoxysilane. Of these, phenyltrimethoxysilane and phenyltriethoxysilane are preferable because they are high in compatibility with resin that contains a repeating unit as represented by the chemical formula (1) or (2) as primary component. Each of these compounds may be contained singly or two or more thereof may be contained in combination.

Examples of a compound other than the compounds represented by the chemical formula (31) and suitable as the compound (b) include tetramethoxysilane, tetraethoxysilane, tetrapropoxysilane, tetrabutoxysilane, tetraphenoxysilane, dimethoxydimethylsilane, diethoxydimethylsilane, dimethoxydiphenylsilane, diethoxydiphenylsilane, and diphenylsilane diols. Of these, dimethoxydiphenylsilane, diethoxydiphenylsilane, and diphenylsilane diols are preferable because they are high in compatibility with resin that contains a repeating unit as represented by the chemical formula (1) or (2) as primary component. Each of these compounds may be contained singly or two or more thereof may be contained in combination. Furthermore, they may be contained in combination with compounds as represented by the chemical formula (31), and preferable combinations include phenyltrimethoxysilane and dimethoxydiphenylsilane, phenyltrimethoxysilane and diethoxydiphenylsilane, phenyltrimethoxysilane and diphenylsilane diol, phenyltriethoxysilane and dimethoxydiphenylsilane, phenyltriethoxysilane and diethoxydiphenylsilane, and phenyltriethoxysilane and diphenylsilane diol.

For the resin composition according to the present invention, such a compound as represented by the chemical formula (3) may be replaced with a condensation product produced therefrom. As described above, a condensation product can be produced by forming siloxane bonds through hydrolysis of alkoxy groups and subsequent dehydration condensation.

In the resin composition, the compound etc. (b) preferably accounts for 5 parts by mass or more, more preferably 10 parts by mass or more, and preferably 200 parts by mass or less, more preferably 100 parts by mass or less, relative to 100 parts by mass of the resin (a). If the content is 5 parts by mass or more, it serves to produce a resin film having a further improved light permeability, whereas if it is 200 parts by mass or less, it serves to produce a resin film having further improved mechanical characteristics.

(Solvent (c))

The resin composition according to the present invention may contain an solvent (c). The inclusion of a solvent allows the resin composition to be used as varnish. By spreading such a varnish on various supports, a coating film including a resin containing a repeating unit as represented by the chemical formula (1) or (2) as primary component can be formed on the supports. Then, a polyimide film that can be used as a substrate for a display device or light receiving device can be produced by curing the resulting coating film by heat treatment.

There are no specific limitations on the solvent, and generally known ones can be used. Examples include N-methyl-2-pyrrolidone, N,N-dimethylformamide, N,N-dimethylacetamide, N,N-dimethylisobutylamide, 3-methoxy-N,N-dimethylpropionamide, 3-butoxy-N,N-dimethylpropionamide, γ-butyrolactone, ethyl lactate, 1,3-dimethyl-2-imidazolidinone, N,N′-dimethylpropyleneurea, 1,1,3,3-tetramethylurea, dimethylsulfoxide, sulfolane, propylene glycol monomethyl ether, propylene glycol monomethyl ether acetate, diethylene glycol ethyl methyl ether, diethylene glycol dimethyl ether, water, and solvents as specified in International Publication WO 2017/099183, which may be used singly or as a mixture of two or more thereof.

In the resin composition, the solvent preferably accounts for 50 parts by mass or more, more preferably 100 parts by mass or more, and preferably 2,000 parts by mass or less, more preferably 1,500 parts by mass or less, relative to 100 parts by mass of the resin (a). If it is in the range where these requirements are met, a viscosity suitable for coating can be achieved to allow an appropriate film thickness to be realized after coating.

The resin composition according to the present invention preferably has a viscosity of 20 to 10,000 mPa·s, more preferably 50 to 8,000 mPa·s. It will be impossible to produce a resin film with a sufficiently large film thickness if the viscosity less than 20 mPa·s, whereas coating with the resin composition will be difficult if it is more than 10,000 mPa·s.

(Additives)

In addition to the resin (a), compound (b), and solvent (c), the resin composition according to the present invention may contain at least one additive selected from the following: (d) photoacid generation agent, (e) thermal crosslinking agent, (f) thermal acid generating agent, (g) compound containing a phenolic hydroxy group, (h) adhesion improver, (i) inorganic particle, and (j) surface active agent. Specific examples of these additives include those specified in International Publication WO 2017/099183.

(d) Photoacid Generation Agent

The resin composition according to the present invention can work as a photosensitive resin composition if it contains a photoacid generation agent. The inclusion of a photoacid generating agent serves to produce an acid in a light-irradiated portion so that the irradiated portion increases in solubility in an aqueous alkali solution, resulting in a positive type relief pattern in which the irradiated portion is dissolvable. If an epoxy compound or such a thermal crosslinking agent as described later is contained in addition to the photoacid generating agent, an acid is generated in a light-irradiated portion to promote crosslinking reaction of the epoxy compound or thermal crosslinking agent, resulting in a negative type relief pattern in which the irradiated portion is insolubilized.

Examples of the photoacid generating agent include quinonediazide compounds, sulfonium salts, phosphonium salts, diazonium salts, and iodonium salts. Two or more thereof may be contained, and a photosensitive resin composition with high sensitivity can be obtained.

(e) Thermal Crosslinking Agent

The resin composition according to the present invention may contain a thermal crosslinking agent so that a resin film produced by heating will have an increased chemical resistance, hardness, etc. The content of the thermal crosslinking agent is preferably 10 parts by mass or more and 100 parts by mass or less relative to 100 parts by mass of the resin (a). If the content is 10 parts by mass or more and 100 parts by mass or less, it ensures the production of a resin film with high strength and a resin composition with high storage stability.

(f) Thermal Acid Generating Agent

The resin composition according to the present invention may further contain a thermal acid forming agent. A thermal acid generating agent generates an acid when heated after development as described below. It then promotes the crosslinking reaction between the resin (a) and the thermal crosslinking agent and also promotes the curing reaction. This serves to provide a resin film with an improved chemical resistance, serving to reduce the film loss. The acid generated from the thermal acid generating agent is preferably a strong acid, which is preferably an aryl sulfonic acid such as p-toluene sulfonic acid and benzene sulfonic acid or an alkyl sulfonic acid such as methane sulfonic acid, ethane sulfonic acid, and butane sulfonic acid. The content of the thermal acid generating agent is preferably 0.5 part by mass or more and 10 parts by mass or less relative to 100 parts by mass of the resin (a) from the viewpoint of promoting the crosslinking reaction.

(g) Compound Containing Phenolic Hydroxy Group

The photosensitive resin composition may contain a compound having a phenolic hydroxy group as required with the aim of helping the alkaline development thereof. If a compound having a phenolic hydroxy group is contained, the resulting photosensitive resin composition will be scarcely dissolved in an alkaline developer before light exposure, but will be easily dissolved in an alkaline developer after light exposure, leading to a decreased film loss during development and ensuring rapid and easy development. Accordingly, the sensitivity can be improved easily. Such a compound having a phenolic hydroxy group preferably accounts for 3 parts by mass or more and 40 parts by mass or less relative to 100 parts by mass of the resin (a).

(h) Adhesion Improver

The varnish according to the present invention may further contain an adhesion improver. Such an adhesion improver is preferably a silane compound that is not a compound as represented by the chemical formula (3) and that contains an alkoxysilyl group and a reactive functional group that is not an alkoxysilyl group. Examples thereof include silane coupling agents such as 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethoxysilane, 3-methacryloxypropyltrimethoxysilane, 3-methacryloxypropylmethyldiethoxysilane, 3-methacryloxypropyltriethoxysilane, N (aminoethyl)-3-aminopropyltrimethoxysilane, N-phenyl-3-aminopropyltrimethoxysilane, tris-(trimethoxysilylpropyl)isocyanurate, 3-ureidopropyltriethoxysilane, 3-ureidopropyltrimethoxysilane, 3-ureidopropylmethoxydiethoxysilane, 3-ureidopropyldimethoxyethoxysilane, 3-isocyanatepropyltriethoxysilane, 3-trimethoxysilylpropylsuccinic anhydride, 4-aminophenyltrimethoxysilane, 4-aminophenyltriethoxysilane, 4-aminophenylmethyldimethoxysilane, 4-aminophenylmethyldiethoxysilane, 3-aminophenyltrimethoxysilane, 3-aminophenyltriethoxysilane, 3-aminophenylmethyldimethoxysilane, 3-aminophenylmethyldiethoxysilane, 2-aminophenyltrimethoxysilane, 2-aminophenyltriethoxysilane, 2-aminophenylmethyldimethoxysilane, 2-aminophenylmethyldiethoxysilane, 3-aminopropyltrimethoxysilane, 3-aminopropyltriethoxysilane, 3-aminopropylmethyldimethoxysilane, and 3-aminopropylmethyldiethoxysilane. If these adhesion improvers are contained, the photosensitive resin film can come in stronger contact with the substrate material such as silicon wafer, ITO, SiO₂, and silicon nitride during the development step. Besides, improved adhesion between the resin film and the substrate material can serve to increase the resistance to oxygen plasma and UV ozone treatment performed for cleaning etc. In addition, it serves to suppress the lifting of the film from the substrate, generally called film lifting, that can occur in a vacuum process for baking, display production, etc. The content of the adhesion improver is preferably 0.005 to 10 parts by mass relative to 100 parts by mass of the resin (a).

(i) Inorganic Particle

The resin composition according to the present invention may contain inorganic particles with the aim of improving the heat resistance. Materials of inorganic particles that serve for this aim include metals such as platinum, gold, palladium, silver, copper, nickel, zinc, aluminum, iron, cobalt, rhodium, ruthenium, tin, lead, bismuth, and tungsten and metal oxides such as silicon oxide (silica), titanium oxide, aluminum oxide, zinc oxide, tin oxide, tungsten oxide, zirconium oxide, calcium carbonate, and barium sulfate. There are no specific limitations on the shape of these inorganic particles, and they may be spherical, elliptic, flattened, rod-like, or fibrous. To prevent an increase in the surface roughness of a resin film containing inorganic particles, the average particle diameter of the inorganic particles is preferably 1 nm or more and 100 nm or less, more preferably 1 nm or more and 50 nm or less, and still more preferably 1 nm or more and 30 nm or less.

The content of the inorganic particles is preferably 3 parts by mass or more, more preferably 5 parts by mass or more, and still more preferably 10 parts by mass or more, and preferably 100 parts by mass or less, more preferably 80 parts by mass or less, and still more preferably 50 parts by mass or less, relative to 100 parts by mass of the resin (a). The heat resistance will be sufficiently high if the above content is 3 parts by mass or more, and the resulting resin film will not suffer a significant decrease in toughness if it is 100 parts by mass or less.

(j) Surface Active Agent

The resin composition according to the present invention may contain a surface active agent in order to improve the coatability. Useful surface active agents include fluorochemical surface active agents such as Fluorad® manufactured by Sumitomo 3M, Megafac® manufactured by DIC Corporation, Surflon® manufactured by Asahi Glass Co., Ltd.; organic siloxane surface active agents such as KP341 manufactured by Shin-Etsu Chemical Co. Ltd., DBE manufactured by Chisso Corporation, Polyflow® and Glanol® manufactured by Kyoeisha Chemical Co., Ltd., and BYK manufactured by BYK-Chemie; and acrylic polymer surface active agents such as Polyflow manufactured by Kyoeisha Chemical Co., Ltd. The content of these surface active agents is preferably 0.01 to 10 parts by mass relative to 100 parts by mass of the resin (a).

<Production Methods for Resin Composition>

A resin composition in the form of a varnish according to an embodiment of the present invention can be produced by, for example, dissolving the resin (a) and the compound etc. (b) in a solvent, along with a photoacid generating agent, thermal crosslinking agent, thermal acid generating agent, compound containing a phenolic hydroxyl group, adhesion improver, inorganic particles, surface active agent, etc., as required. This dissolution can be carried out by stirring, heating, etc. If a photoacid generating agent is contained, an appropriate heating temperature is adopted in a range, commonly from room temperature to 80° C., where a photosensitive resin composition with unimpaired performance is obtained. There are no specific limitations on the order of dissolving these components, and for example, the compound with the lowest solubility may be dissolved first followed by others in the order of solubility. Alternatively, the dissolution of those components, such as surface active agent, that are likely to form bubbles when dissolved by stirring may be preceded by the dissolution of the other components so that the dissolution of the latter will not be hindered by bubble formation.

Here, the resin (a) can be polymerized by a known method. For example, polyamic acid can be produced by polymerizing an acid component such as tetracarboxylic acid, a corresponding acid dianhydride, active ester, and active amide with a diamine component such as diamine and a corresponding trimethylsilylated diamine in a reaction solvent. Here, the carboxyl group in the polyamic acid may be in a salified state with an alkali metal ion, ammonium ion, or imidazolium ion or in an esterified state with a hydrocarbon group containing 1 to 10 carbon atoms or an alkyl silyl group containing 1 to 10 carbon atoms. On the other hand, polyimide can be produced by imidizing a polyamic acid by a method as described later.

There are no specific limitations on the reaction solvent, and generally known ones can be used. Examples thereof include N-methyl-2-pyrrolidone, N,N-dimethylformamide, N,N-dimethylacetamide, N,N-dimethylisobutylamide, 3-methoxy-N,N-dimethylpropionamide, 3-butoxy-N,N-dimethylpropionamide, γ-butyrolactone, ethyl lactate, 1,3-dimethyl-2-imidazolidinone, N,N′-dimethylpropyleneurea, 1,1,3,3-tetramethylurea, dimethylsulfoxide, sulfolane, propylene glycol monomethyl ether, propylene glycol monomethyl ether acetate, diethylene glycol ethyl methyl ether, diethylene glycol dimethyl ether, water, and reaction solvents as specified in International Publication WO 2017/099183, which may be used singly or as a mixture of two or more thereof.

It is preferable for the quantity of the reaction solvent to be adjusted so that the tetracarboxylic acid and the diamine compound altogether account for 0.1 to 50 mass % of the total quantity of the reaction solution. The reaction temperature is preferably −20° C. to 150° C., and more preferably 0° C. to 100° C. Furthermore, the reaction period is preferably 0.1 to 24 hours, and more preferably 0.5 to 12 hours. Here, it is preferable for the number of moles of the diamine compound to be equal to that of the tetracarboxylic acid. When they are equal, a resin film having good mechanical characteristics can be produced easily from a resin composition.

The resulting polyamic acid may be used directly as a resin composition according to the present invention. In this case, the intended resin composition can be obtained without isolating the resin if the same solvent as intended for the resin composition is adopted as the reaction solvent or an appropriate solvent is added after the completion of the reaction.

Furthermore, the resulting polyamic acid may be modified by imidizing or esterifying part of or all of the repeating units in the polyamic acid. In this case, the polyamic acid solution resulting from polymerization of the polyamic acid may be applied directly to the next reaction step or the polyamic acid may be isolated before applying it to the next reaction step.

In the esterification and imidization reactions as well, the same solvent as the one to be used for preparing a resin composition may be adopted as the reaction solvent or an appropriate solvent may be added after the completion of the reaction in order to produce the intended resin composition without isolating the resin.

For the imidization, it is preferable to adopt a method designed to heat the polyamic acid or a method designed to adding a dehydrating agent and imidization catalyst, followed by heating if required. The former method is more preferable because the latter method requires a step for removing reaction products of the dehydrating agent, the imidization catalyst, and the like. There are no specific limitations on the dehydrating agent and imidization catalyst, and generally known ones can be used.

Useful reaction solvents for the imidization reaction include those listed above as examples for the polymerization reaction.

The imidization reaction temperature is preferably 0° C. to 180° C., and more preferably 10° C. to 150° C. The reaction period is preferably 1.0 to 120 hours, and more preferably 2.0 to 30 hours. Setting an appropriate reaction temperature and reaction period in these ranges allows the polyamic acid to be imidized to an intended degree.

For the esterification, it is preferable to adopt a method designed to cause a reaction with an esterifying agent or a method designed to cause a reaction with an alcohol in the presence of a dehydration condensation agent. There are no specific limitations on the solvent to be used for the esterification reaction and reaction conditions, and generally known ones can be used.

The varnish produced by any of these production methods is preferably filtrated through a filter to remove extraneous materials such as dust.

<Production Method for Resin Film>

The method for producing a resin film from a resin composition according to the present invention includes a step (A) for spreading a resin composition on a support and a step (B) for heating the resulting coating film to form a resin film on the support.

First, a varnish that is a resin composition according to an embodiment of the present invention is spread on a support. Good examples of such a support include wafer substrates of silicon, gallium arsenide, or the like; glass substrates of sapphire glass, soda lime glass, alkali-free glass, or the like; metal substrates of stainless steel, copper, or the like; and others such as metal foil and ceramic substrate. Of these, alkali-free glass is preferable from the viewpoint of surface smoothness and dimensional stability during heating.

Useful varnish coating methods include spin coating, slit coating, dip coating, spray coating, and printing, which may be used in combination. When a resin film used as a substrate for a display device or a light receiving device, it will be necessary to spread the varnish over a support with a large size and accordingly, the use of the slit coating method is particularly preferred.

The support may be pre-treated in advance before coating. For example, a pretreatment agent is dissolved to 0.5 to 20 mass % in a solvent such as isopropanol, ethanol, methanol, water, tetrahydrofuran, propylene glycol monomethyl ether acetate, propylene glycol monomethyl ether, ethyl lactate, and diethyl adipate to prepare a solution, which is then used to treat the support surface by an appropriate technique such as spin coating, slit die coating, bar coating, dip coating, spray coating, and steam processing. Vacuum drying may be carried out as required, followed by heat treatment at 50° C. to 300° C. to accelerate the reaction between the support and the pretreatment agent.

The coating step is commonly followed by drying the varnish coating film. Useful drying methods include reduced pressure drying, thermal drying, etc., and combinations thereof. Reduced pressure drying can be carried out by, for example, a process in which a support with a coating film formed thereon is put in a vacuum chamber, followed by reducing the pressure in the vacuum chamber. Thermal drying can be performed by using a tool such as hot plate, oven, and infrared ray. When using a hot plate, the coating film is put directly on the plate or held on jigs such as proxy pins fixed on the plate, followed by heat-drying.

When the resin composition according to the present invention contains a photoacid generating agent, a pattern can be formed by processing the dried coating film by the method described below. To perform light exposure, an actinic ray is applied to the coating film through a mask having an intended pattern. There are various useful actinic rays for light exposure including ultraviolet ray, visible light, electron beam, and X-ray, but the i-line (365 nm), h-line (405 nm), and g-line (436 nm) of mercury lamps are preferred for the present invention. If it is positively photosensitive, the light-exposed region dissolves in a developer. If it is negatively photosensitive, the light-exposed region hardens and becomes insoluble in a developer.

After the exposure step, a developer is used to remove the light-exposed region of a positive type film or the unexposed region of a negative type film to form an intended pattern. There are no specific limitations on the developer, and generally known ones can be used (for example, developers as specified in International Publication WO 2017/099183). Of these, the use of an aqueous solution of an alkaline compound such as tetramethylammonium, sodium hydroxide, potassium hydroxide, sodium carbonate, and potassium carbonate is preferable regardless of whether the film is of positive type or negative type. For negative type films, organic solvents such as N-methyl-2-pyrrolidone, N,N-dimethylformamide, N,N-dimethylacetamide, dimethylsulfoxide, γ-butyrolactone, ethyl lactate, propylene glycol monomethyl ether acetate, cyclopentanone, cyclohexanone, and methyl isobutyl ketone can also be used. Commonly, rinsing with water is performed after the development step.

Finally, a heat resistant resin film can be produced by performing heat-treatment in the range of 180° C. or more and 600° C. or less to bake the coating film. Heating is performed preferably at 430° C. or more, whereas heating is performed preferably at 490° C. or less. Display devices are generally manufactured at temperatures higher than 400° C., and therefore, resin films that are resistant to such temperatures are required. If the baking is performed at 430° C. or more, it serves to produce a resin film having a high heat resistance. On the other hand, if heating is performed at 490° C. or less, thermal decomposition of the resin is suppressed, leading to a resin film with a low yellowness index.

<Resin Film>

For the present invention, there are no specific limitations on the film thickness of the resin film, but the film thickness is preferably 3 μm or more. The thickness is more preferably 5 μm or more, and still more preferably 7 μm. On the other hand, the film thickness is preferably 100 μm or less. The thickness is more preferably 50 μm or less, and still more preferably 30 μm or less. If having a thickness of 3 μm or more, the film will have adequate mechanical characteristics to serve as a substrate for a display device or a light receiving device. If having a thickness of 100 μm or less, the film will have a particularly high toughness to serve as a substrate for a display device or a light receiving device.

The resin film according to the present invention can be used as a substrate for various electronic devices. In particular, such a substrate can be used suitably for display devices such as organic EL display, liquid crystal display, micro LED display, electronic paper, and touch panel, and light receiving devices such as X-ray receiving sensor, solar battery, and scintillator. Conventionally, these devices are produced by using a large glass plate as substrate and forming various elements thereon. Therefore, a device having a resin film as substrate can be produced if a glass substrate is used as support and a resin composition is spread thereon and cured by heating to produce a resin film, followed by similarly forming various elements and finally removing the glass substrate.

In general, when a resin film is used as substrate for a display device or a light receiving device, it will be subjected to the next step without removing it from the support. However, the resin film may be subjected to the next step after removing it from the support by the peeling method described later. In the case where it is not peeled before sending it to the next step, the stress that occurs is preferably 25 MPa or less in order to prevent a decrease in processability from being caused by warp of the support. In general, the stress is measured using a thin film stress measuring device. In this device, the degree of warp of a substrate having a polyimide film formed thereon is measured and the stress is calculated therefrom. Here, if the polyimide film absorbs water, it affects the measurement, and therefore, measurements taken from a dried polyimide film are adopted.

<Substrate for Display Device or Light Receiving Device>

An embodiment of the present invention provides a substrate for a display device or light receiving device that includes a resin having a repeating unit as represented by the chemical formula (1) as primary component and polysiloxane and shows a weight loss starting temperature of 400° C. or more and a yellowness index of 3.5 or less.

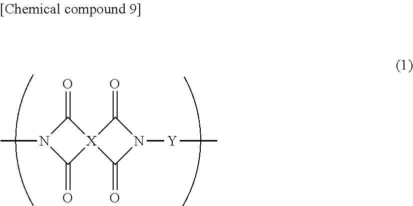

In the chemical formula (1), X denotes a tetravalent tetracarboxylic acid residue containing 2 or more carbon atoms and Y denotes a divalent diamine residue containing 2 or more carbon atoms. Details of the chemical formula (1), necessity for a weight loss starting temperature of 400° C. or more and a yellowness index of 3.5 or less, and preferable ranges thereof are as described for the resin composition according to the present invention.

In particular, the use of a substrate containing polysiloxane serves to increase the weight loss starting temperature while decreasing the yellowness index. The polysiloxane is preferably silsesquioxane and is more preferably a polysiloxane produced through hydrolysis and condensation of the compound (b). In this case, the above effects are enhanced particularly markedly.

In a substrate for a display device or light receiving device according to the present invention, 50 mol % or more of the repeating units represented by the chemical formula (1) is preferably accounted for by repeating units in which Y is a structure as represented by the chemical formula (11), and 50 mol % or more of the repeating units represented by the chemical formula (1) is preferably accounted for by repeating units in which X is a structure as represented by the chemical formula (12).

There are no specific limitations on the method to use to produce the aforementioned substrate, but a resin film produced from the resin composition according to the present invention can be used to provide the substrate.

<Display Device or Light Receiving Device>

A device according to the present invention is one including a substrate as described above having a displaying element or a light receiving element formed thereon. Examples of the display element include organic EL element, liquid crystal display element, micro LED element, drive element for electronic paper, touch panel member, and color filter. Examples of the light receiving element include X-ray receiving element, solar battery cell, scintillator panel, and image sensor.

Examples of such a device according to the present invention include a device that contains a substrate as described above having a display element formed on a surface thereof and a light receiving element formed on the other surface. In a typical process, an organic EL element that serves as a display element is formed first on a substrate according to the present invention to prepare an organic EL panel. Elsewhere, a silicon substrate is used to prepare an image sensor containing a CMOS sensor element. For the above organic EL panel, an image sensor is attached to the surface opposite to the one having an organic EL element to provide a panel that combines a display element and a light receiving element. The substrate according to the present invention is so small in yellowness index that a beam incident to the surface having the organic EL element reaches the light receiving element with little intensity loss. As a result, this can perform sensing of light in spite of the existence of a display element in front of the light receiving element. Thus, restrictions on the arrangement of each element are reduced, advantageously allowing the device to have an increased degree of design freedom.

<Production Method for Display Device or Light Receiving Device>

The method for producing a display device or a light receiving device from the resin composition according to the present invention includes the step (A) and the step (B) included in the production method for the resin film, and an additional step (C) for forming a display device or a light receiving device on the resin film.

First, the step (A) and the step (B) described above are carried out to produce a resin film on a support such as glass substrate. Here, a primer layer may be formed on the support in advance in order to facilitate the peeling of the film from the support described later. For example, a mold releasing agent may be applied to the support, or a sacrifice layer may be formed. Useful mold releasing agents include silicone based, fluorine based, aromatic polymer based, and alkoxysilane based ones. Useful sacrifice layers include metal film, metal oxide film, and amorphous silicon film.

An inorganic film is provided if required on the resin film formed above. This serves to prevent moisture, oxygen, or the like existing outside the substrate from passing through the resin film to cause degradation of the pixel driving device, light emitting device, or the like. The inorganic film may be of, for example, silicon oxide (SiOx), silicon nitride (SiNy), or silicon oxynitride (SiOxNy), which may be in the form of a monolayer or a plurality of stacked layers of different materials. Such inorganic film layers may be, for example, stacked alternately with film layers of organic material such as polyvinyl alcohol. To produce such inorganic films, it is preferable to use a deposition method such as the chemical vapor deposition (CVD) technique and the physical vapor deposition (PVD) technique.

If required, a resin film may be formed on the inorganic film or an inorganic film may be formed additionally in order to produce a substrate for a display device or light receiving device that contains a plurality of inorganic film layers or resin film layers. From the viewpoint of process simplification, it is preferable to use the same resin composition for forming these resin films.

Following this, components of the display element or light receiving element are formed on the resulting resin film (or on top of the inorganic film etc. if any). In the case of an organic EL display, for example, a TFT, which works as image driving device, a first electrode, an organic EL light emitting device, a second electrode, and sealing film are formed in this order to produce an image display element. In the case of a substrate for a color filter, a black matrix is formed as required, followed by forming color pixels of red, green, blue, etc. In the case of a substrate for a touch panel, a wiring layer and an insulation layer are formed.

In the step for forming an inorganic film and the step for forming a TFT described above, treatment is likely to be performed at a temperature of 400° C. or more, and therefore, the resin film preferable does not suffer thermal decomposition in such a temperature range. It is more preferably free of thermal decomposition at 430° C. or more, and still more preferably 450° C. or more.

To allow the device according to the present invention to serve as a flexible device, it is preferable to add a final step (D) for removing the support. The support is removed by separating the support and the resin film along the interface between them. Good methods for the separation include laser lift-off, mechanical peeling, and etching of the support. To perform laser lift-off for a support such as glass substrate, a laser beam is applied to the surface opposite the one carrying a resin film and element. This makes it possible to separate them without causing damage to the element.

A laser beam in the wavelength range from ultraviolet light to infrared light can be used, and the use of ultraviolet light is particularly preferable. It is more preferable to use an excimer laser of 308 nm. The separation energy is preferably 250 mJ/cm² or less, and more preferably 200 mJ/cm² or less.

An electronic device located on a resin film is produced through these steps, and it is modularized as required to provide a final product. The resin film according to the present invention is so small in haze and yellowness index that it can be incorporated in a transparent type display that requires a highly colorless and transparent substrate. Furthermore, in the case where a light receiving element is formed on the surface opposite to the one that carries a display element or in the case where another light receiving device is added, the light receiving element and light receiving device react also to beams incident to the display side and passing through the resin film. This serves to allow the electronic device to have a higher degree of design freedom. If these uses are assumed, the haze is preferably 1% or less, more preferably 0.5% or less, and still preferably 0.1% or less.

### EXAMPLES

The present invention will be illustrated below in greater detail with reference to examples etc., though the present invention is not limited to the examples etc. given below. First, the procedures for measurement, evaluation, test, etc. performed in the examples and comparative examples given below will be described. It is noted that only one measurement is taken (n=1) unless otherwise specified.

(Measurement of Thickness of Resin Film)

Measurements were taken from the resin film prepared in each Example and Comparative example using a digital length measuring machine equipped with a built-in linear encoder (manufactured by Nicon Corporation, head: MF-501, counter: MFC-101 A, stand: MS-11C).

(Measurement of Light Transmittance of Resin Film)

The resin film prepared in each Example and Comparative example was attached to a glass substrate, and the light transmittance of the resin film at a wavelength of 400 nm was determined using an ultraviolet-visible spectrophotometer (MultiSpec 1500, manufactured by Shimadzu Corporation). The glass substrate was used as reference sample.

(Measurement of Yellowness Index of Resin Film)

Measurements were taken from the resin film prepared in each Example and Comparative example using a spectroscopic haze meter (HSP-150Vis, manufactured by Murakami Color Research Laboratory Co., Ltd.) according to JIS K 7373 (2006).

(Measurement of Haze of Resin Film)

Measurements were taken from the resin film prepared in each Example and Comparative example using a spectroscopic haze meter (HSP-150Vis, manufactured by Murakami Color Research Laboratory Co., Ltd.) according to JIS K 7136 (2000).

(Measurement of Weight Loss Starting Temperature of Resin Film)

The weight loss starting temperature of the resin film (sample) prepared in each Example was measured using a thermogravimetric analyzer (TGA-50, manufactured by Shimadzu Corporation Inc.). The heating conditions were as follows. In the first step, the sample was heated to 150° C. at a heating rate of 10° C./min and maintained at 150° C. for 30 minutes. This served to remove adsorbed water from the sample. Then, in the second step, the sample was air-cooled to room temperature at a cooling rate of 10° C./min. Subsequently, in the third stage, it was heated at a heating rate of 10° C./min, and the temperature at which weight loss started was determined as the weight loss starting temperature. All steps were carried out in in a dried nitrogen atmosphere.

(Chemical Compounds)

Compounds as listed below were adopted appropriately in Examples and Comparative examples. The names and abbreviations of the compounds are follows.

BPDA: 3,3′,4,4′-biphenyltetracarboxylic dianhydride (manufactured by Mitsubishi Chemical Corporation)

ODPA: 4,4′-oxydiphthalic dianhydride (manufactured by Manac Incorporated)

6FDA: 4,4′-(hexafluoroisopropylidene)diphthalic anhydride (manufactured by Daikin Industries, Ltd.)

4,4′-DDS: 4,4′-diaminodiphenylsulfone (manufactured by Seika Corporation)

3,3′-DDS: 3,3′-diaminodiphenylsulfone (manufactured by Seika Corporation)

TFMB: 2,2′-(trifluoromethyl)benzidine (manufactured by Seika Corporation)

KBM-103: phenyltrimethoxysilane (manufactured by Shin-Etsu Chemical Co., Ltd.)

KBM-04: tetramethoxysilane (manufactured by Shin-Etsu Chemical Co., Ltd.)

KBM-202SS: diphenyldimethoxysilane (manufactured by Shin-Etsu Chemical Co., Ltd.)

### Synthesis Example 1

A thermometer and a stirring rod equipped with stirring blades were fitted on a 300 mL four-necked flask. Then, in a dry nitrogen flow, NMP (140 g) and 4,4′-DDS (24.58 g (99.00 mmol)) were added, and the temperature was elevated to 40° C. After the temperature elevation, BPDA (29.42 g (100.0 mmol)) was added while stirring, followed by washing with NMP (20 g). Stirring was performed at 60° C. for 6 hours to provide a solution A.

### Synthesis Example 2

A thermometer and a stirring rod equipped with stirring blades were fitted on a 300 mL four-necked flask. Then, in a dry nitrogen flow, NMP (140 g) and 3,3′-DDS (24.58 g (99.00 mmol)) were added, and the temperature was elevated to 40° C. After the temperature elevation, BPDA (29.42 g (100.0 mmol)) was added while stirring, followed by washing with NMP (20 g). Stirring was performed at 60° C. for 6 hours to provide a solution B.

### Synthesis Example 3

A thermometer and a stirring rod equipped with stirring blades were fitted on a 300 mL four-necked flask. Then, in a dry nitrogen flow, NMP (140 g) and 4,4′-DDS (24.58 g (99.00 mmol)) were added, and the temperature was elevated to 40° C. After the temperature elevation, ODPA (31.02 g (100.0 mmol)) was added while stirring, followed by washing with NMP (20 g). Stirring was performed at 60° C. for 6 hours to provide a solution C.

### Synthesis Example 4

A thermometer and a stirring rod equipped with stirring blades were fitted on a 300 mL four-necked flask. Then, in a dry nitrogen flow, NMP (140 g) and TFMB (31.70 g (99.00 mmol)) were added, and the temperature was elevated to 40° C. After the temperature elevation, BPDA (29.42 g (100.0 mmol)) was added while stirring, followed by washing with NMP (20 g). Stirring was performed at 60° C. for 6 hours to provide a solution D.

### Synthesis Example 5

A thermometer and a stirring rod equipped with stirring blades were fitted on a 300 mL four-necked flask. Then, in a dry nitrogen flow, NMP (140 g) and 4,4′-DDS (24.58 g (99.00 mmol)) were added, and the temperature was elevated to 40° C. After the temperature elevation, 6FDA (44.42 g (100.0 mmol)) was added while stirring, followed by washing with NMP (20 g). Stirring was performed at 60° C. for 6 hours to provide a solution E.

### Synthesis Example 6

A thermometer and a stirring rod equipped with stirring blades were fitted on a 300 mL four-necked flask. Then, in a dry nitrogen flow, NMP (90 g), KBM-103 (80.0 g (403.4 mmol)), water (25 g), and phosphoric acid (5 g) were added, and the temperature was elevated to 70° C. After the temperature elevation, stirring was performed for 1 hour to provide a solution Z.

### Preparation Example 1

To the solution A produced in Synthesis example 1, 40 parts by weight of KBM-103 (assuming that the resin contained in the solution A accounts for 100 parts by weight) was added, followed by stirring. After the stirring, it was filtered through a filter of high density polyethylene with a pore size of 0.2 μm to prepare a varnish a1.

### Preparation Example 2

To the solution A produced in Synthesis example 1, 20 parts by weight each of KBM-103 and KBM-04 (assuming that the resin contained in the solution A accounts for 100 parts by weight) were added, followed by stirring. After the stirring, it was filtered through a filter of high density polyethylene with a pore size of 0.2 μm to prepare a varnish a2.

### Preparation Example 3

To the solution A produced in Synthesis example 1, 20 parts by weight each of KBM-103 and KBM-202SS (assuming that the resin contained in the solution A accounts for 100 parts by weight) were added, followed by stirring. After the stirring, it was filtered through a filter of high density polyethylene with a pore size of 0.2 μm to prepare a varnish a3.

### Preparation Example 4

To the solution A produced in Synthesis example 1, 100 parts by weight of the solution Z (assuming that the resin contained in the solution A accounts for 100 parts by weight) was added, followed by stirring. After the stirring, it was filtered through a filter of high density polyethylene with a pore size of 0.2 μm to prepare a varnish a4.

### Preparation Example 5

To the solution B produced in Synthesis example 1, 40 parts by weight of KBM-103 (assuming that the resin contained in the solution B accounts for 100 parts by weight) was added, followed by stirring. After the stirring, it was filtered through a filter of high density polyethylene with a pore size of 0.2 μm to prepare a varnish a5.

### Preparation Example 6

To the solution C produced in Synthesis example 1, 40 parts by weight of KBM-103 (assuming that the resin contained in the solution C accounts for 100 parts by weight) was added, followed by stirring. After the stirring, it was filtered through a filter of high density polyethylene with a pore size of 0.2 μm to prepare a varnish a6.

### Preparation Example 7

Without adding any compound, the solution A produced in Synthesis example 1 was filtered through a filter of high density polyethylene with a pore size of 0.2 μm to prepare a varnish a7.

### Preparation Example 8

To the solution A produced in Synthesis example 1, 40 parts by weight of KBM-04 (assuming that the resin contained in the solution A accounts for 100 parts by weight) was added, followed by stirring. After the stirring, it was filtered through a filter of high density polyethylene with a pore size of 0.2 μm to prepare a varnish a8.

### Preparation Example 9

To the solution A produced in Synthesis example 1, 40 parts by weight of KBM-202SS (assuming that the resin contained in the solution A accounts for 100 parts by weight) was added, followed by stirring. After the stirring, it was filtered through a filter of high density polyethylene with a pore size of 0.2 μm to prepare a varnish a9.

### Preparation Example 10

Without adding any compound, the solution B produced in Synthesis example 2 was filtered through a filter of high density polyethylene with a pore size of 0.2 μm to prepare a varnish b1.

### Preparation Example 11

Without adding any compound, the solution C produced in Synthesis example 3 was filtered through a filter of high density polyethylene with a pore size of 0.2 μm to prepare a varnish c1.

### Preparation Example 12

Without adding any compound, the solution D produced in Synthesis example 4 was filtered through a filter of high density polyethylene with a pore size of 0.2 μm to prepare a varnish d1.

### Preparation Example 13

Without adding any compound, the solution E in Synthesis example 5 was filtered through a filter of high density polyethylene with a pore size of 0.2 μm to prepare a varnish el.

### Example 1

The varnish prepared in Preparation example 1 was adopted. Using a slit coating apparatus (manufactured by Toray Engineering Co., Ltd.), the varnish prepared in Preparation example 1 was spread over the surface of a non-alkali glass substrate (AN100, manufactured by Asahi Glass Co., Ltd.) having a size of 350 mm length×300 mm width×0.5 mm thickness, leaving the 5 mm wide periphery uncoated. Then, heating and drying were performed at 80° C. using the same apparatus. Finally, using a gas oven (INH-21CD, manufactured by Koyo Thermo Systems Ltd.), it was heated in a nitrogen atmosphere (oxygen concentration 100 ppm or less) from room temperature to 130° C. and maintained at 130° C. for 30 minutes, then heated to 220° C. and maintained at 220° C. for 30 minutes, further heated to 430° C. and maintained at 430° C. for 30 minutes, and finally cooled to room temperature to form a resin film with a thickness of 10 μm on the glass substrate. Heating was performed at a rate of 5° C./min. For the glass substrate that carried the resin film produced above, a laser beam having a wavelength of 308 nm was applied to the surface that was not covered by the resin film in order to peel the resin film from the substrate. The light transmittance, yellowness index, haze, and weight loss starting temperature of the resin film were measured by the methods described above.

### Examples 2 to 6 and Comparative Examples 1 to 7

The varnish samples prepared in Preparation examples 2 to 13 were evaluated by the same procedure as in Example 1. Evaluation results obtained in Examples 1 to 6 and Comparative example 1 to 7 are shown in Table 1.

TABLE 1

| | | unit | Example 1 | Example 2 | Example 3 | Example 4 | Example 5 | Example 6 | |
|---|---|---|---|---|---|---|---|---|---|
| resin composition | | | Preparation | Preparation | Preparation | Preparation | Preparation | Preparation | |
| (varnish) | | | example 1 | example 2 | example 3 | example 4 | example 5 | example 6 | |
| resin | | | Synthesis | Synthesis | Synthesis | Synthesis | Synthesis | Synthesis | |
| | | | example 1 | example 1 | example 1 | example 1 | example 2 | example 3 | |
| | | parts by weight | 100 | 100 | 100 | 100 | 100 | 100 | |
| | BPDA | molar ratio | 100 | 100 | 100 | 100 | 100 | | |
| | ODPA | | | | | | | 100 | |
| | 6 FDA | | | | | | | | |
| | 4,4′-DDS | | 99 | 99 | 99 | 99 | | 100 | |
| | 3,3′-DDS | | | | | | 99 | | |
| | TFMB | | | | | | | | |
| additive | KBM-103 | parts by weight | 40 | 20 | 20 | | 40 | 40 | |
| | KBM-04 | parts by weight | | 20 | | | | | |
| | KBM-202 SS | parts by weight | | | 20 | | | | |
| | solution Z | parts by weight | | | | 100 | | | |
| items | transmittance | % | 72 | 70 | 73 | 73 | 73 | 86 | |
| of film | at 400 nm | | | | | | | | |
| properties | haze | % | 0.0 | 0.0 | 0.0 | 0.0 | 0.0 | 0.0 | |
| evaluation | yellowness | | 2.5 | 2.9 | 2.3 | 2.5 | 3.2 | 2.6 | |
| | index | | | | | | | | |
| | weight loss | ° C. | 455 | 454 | 405 | 455 | 435 | 438 | |
| | starting | | | | | | | | |
| | temperature | | | | | | | | |
| | | | Comparative | Comparative | Comparative | Comparative | Comparative | Comparative | Comparative |
| | | unit | example 1 | example 2 | example 3 | example 4 | example 5 | example 6 | example 7 |
| resin composition | | | Preparation | Preparation | Preparation | Preparation | Preparation | Preparation | Preparation |
| (varnish) | | | example 7 | example 8 | example 9 | example 10 | example 11 | example 12 | example 13 |
| resin | | | Synthesis | Synthesis | Synthesis | Synthesis | Synthesis | Synthesis | Synthesis |
| | | | example 1 | example 1 | example 1 | example 2 | example 3 | example 4 | example 5 |
| | | parts by weight | 100 | 100 | 100 | 100 | 100 | 100 | 100 |
| | BPDA | molar ratio | 100 | 100 | 100 | 100 | | 100 | |
| | ODPA | | | | | | 100 | | |
| | 6 FDA | | | | | | | | 100 |
| | 4,4′-DDS | | 99 | 99 | 99 | | 100 | | 99 |
| | 3,3′-DDS | | | | | 99 | | | |
| | TFMB | | | | | | | 99 | |
| additive | KBM-103 | parts by weight | | | | | | | |
| | KBM-04 | parts by weight | | 40 | | | | | |
| | KBM-202 SS | parts by weight | | | 40 | | | | |
| | solution Z | parts by weight | | | | | | | |
| items | transmittance | % | 64 | 55 | 57 | 69 | 75 | 42 | 52 |
| of film | at 400 nm | | | | | | | | |
| properties | haze | % | 0.0 | 0.0 | 1.1 | 0.1 | 0.1 | 0.0 | 0.0 |
| evaluation | yellowness | | 3.9 | 7.4 | 10.3 | 3.9 | 4.7 | 18.7 | 10.1 |
| | index | | | | | | | | |
| | weight loss | ° C. | 462 | 454 | 381 | 386 | 396 | 489 | 407 |
| | starting | | | | | | | | |
| | temperature | | | | | | | | |

### Example 101

A gas barrier film containing SiO₂ and Si₃N₄ layers was formed by CVD on top of the resin film produced on a glass substrate in Example 1. Then, a TFT was formed and an insulation film of Si₃N₄ was formed to cover the TFT. Subsequently, a contact hole was formed through this insulation film, and wiring that connects to the TFT via this contact hole was formed.

In addition, a planarizing film was formed to planarize the irregularities resulting from this wiring. Then, on top of the planarizing film formed above, an ITO-based first electrode that connects to the wiring was formed. Then, the surface was coated with a resist, prebaked, exposed to light through an appropriately patterned mask, and developed. Using this resist pattern as mask, patterning was performed by wet etching with an ITO etchant. Subsequently, the resist pattern was removed using a resist stripping liquid (a liquid mixture of monoethanol amine and diethylene glycol monobutyl ether). After the removal step, the substrate was rinsed and heated for dehydration to provide an electrode substrate having a planarizing film. Next, an insulation film was formed in a shape that covers the periphery of the first electrode.

In addition, in a vacuum deposition apparatus, a hole transport layer, organic light emitting layer, and electron transport layer were deposited in this order through masks of intended patterns. Subsequently, the second electrode of Al/Mg was formed over the entire surface above the substrate. In addition, a sealing film in the form of stacked layers of SiO₂ and Si₃N₄ was formed by CVD. Finally, a laser beam (wavelength 308 nm) was applied through the surface of the glass substrate that was not covered with the resin film, thereby causing peeling along the interface between the substrate and the resin film. In this step, the irradiation energy used was 200 mJ/cm².

In this way, an organic EL display device was produced on a resin film. When a voltage was applied through a drive circuit, it was found to emit light successfully.

### Comparative Example 101

A gas barrier film containing SiO₂ and Si₃N₄ layers was formed by CVD on top of the resin film produced on a glass substrate in Comparative example 3. However, gas was released from the resin film to cause part of the gas barrier film to suffer film lifting and peeling, thus making it impossible to proceed to the subsequent steps.

1. A resin composition designed to produce a resin film to be used as a substrate for a display device or light receiving device, comprising (a) a resin that has a repeating unit as represented by the chemical formula (1) or (2) as primary component and (b) a chemical compound as represented by the chemical formula (3) and/or a condensation product thereof and forming, when heated at 430° C. for 30 minutes, a resin film having a weight loss starting temperature of 400° C. or more and showing a yellowness index of 3.5 or less when being 10 μm thick: 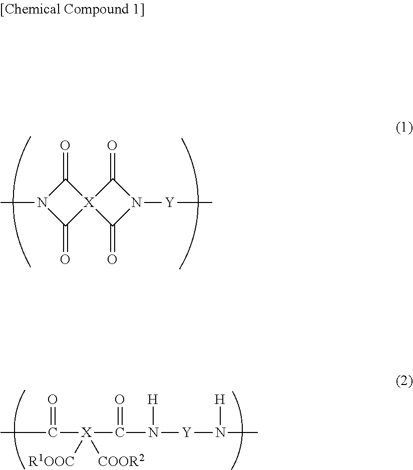
wherein in the chemical formulae (1) and (2), X denotes a tetravalent tetracarboxylic acid residue containing 2 or more carbon atoms and Y denotes a divalent diamine residue containing 2 or more carbon atoms; R¹ and R² each independently denote a hydrogen atom, a hydrocarbon group containing 1 to 10 carbon atoms, an alkyl silyl group containing 1 to 10 carbon atoms, an alkali metal ion, an ammonium ion, an imidazolium ion, or a pyridinium ion;
[Chemical compound 2]
Si(OR¹¹)ₙ(R¹²)₄₋ₙ (3)
wherein in the chemical formula (3), R¹¹ denotes a hydrogen atom or a hydrocarbon group containing 1 to 10 carbon atoms; R¹² denotes a hydrocarbon group containing 1 to 10 carbon atoms; and n represents an integer of 2 to 4.

2. A resin composition as set forth in claim 1, wherein 50 mol % or more of the repeating units represented by the chemical formula (1) or (2) existing in the resin is accounted for by those repeating units in which Y is a structure as represented by the chemical formula (11):

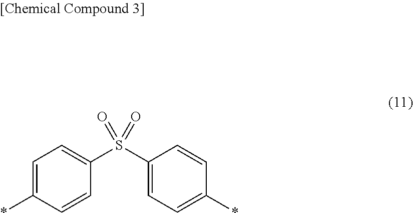

3. A resin composition as set forth in claim 1, wherein 50 mol % or more of the repeating units represented by the chemical formula (1) or (2) existing in the resin is accounted for by those repeating units in which X is a structure as represented by the chemical formula (12):

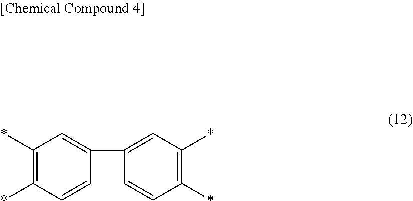

4. A resin composition as set forth in claim 1, wherein the compounds represented by the chemical formula (3) include a compound as represented by the chemical formula (31):
[Chemical compound 5]
Si(OR¹¹)₃(R¹²) (31)
wherein in the chemical formula (31), R¹¹ denotes a hydrogen atom or a hydrocarbon group containing 1 to 10 carbon atoms and R¹² denotes a hydrocarbon group containing 1 to 10 carbon atoms.

5. A resin composition as set forth in claim 1 further comprising a solvent.

6. A production method for a display device or a light receiving device comprising a step (A) for coating a support with a resin composition as set forth in claim 5, a step (B) for heating the resulting coating film to form a resin film on the support, and a step (C) for forming a display device or a light receiving device on the resin film.

7. A production method for a display device or a light receiving device as set forth claim 6 further comprising a step (D) for removing the support.

8. A substrate for a display device or light receiving device comprising a resin having a repeating unit as represented by the chemical formula (1) as primary component and polysiloxane and showing a weight loss starting temperature of 400° C. or more and a yellowness index of 3.5 or less: 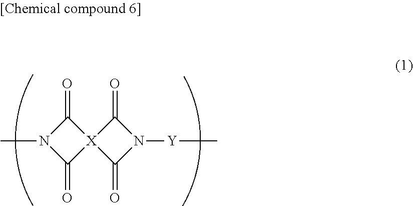
wherein in the chemical formula (1), X denotes a tetravalent tetracarboxylic acid residue containing 2 or more carbon atoms and Y denotes a divalent diamine residue containing 2 or more carbon atoms.

9. A substrate for a display device or light receiving device as set forth in claim in claim 8, wherein the polysiloxane contains a silsesquioxane structural unit.

10. A substrate for a display device or light receiving device as set forth in claim 8, wherein 50 mol % or more of the repeating units represented by the chemical formula (1) existing in the resin is accounted for by those repeating units in which Y is a structure as represented by the chemical formula (11):

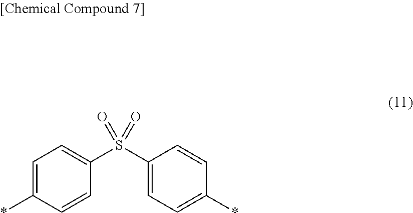

11. A substrate for a display device or light receiving device as set forth in claim 8, wherein 50 mol % or more of the repeating units represented by the chemical formula (1) existing in the resin is accounted for by those repeating units in which X is a structure as represented by the chemical formula (12):

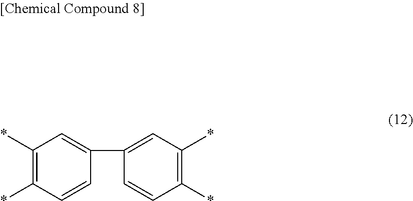

12. A device comprising a display element or a light receiving element formed on a substrate as set forth in claim 8.

13. A device comprising a substrate as set forth in claim 8 having a display element formed on a surface thereof and a light receiving element formed on the other surface.
